(19) United States
(12) Patent Application Publication
(10) Pub. No.: US 2023/0084127 A1
(43) Pub. Date: Mar. 16, 2023

(54) SEMICONDUCTOR DEVICE MANUFACTURING METHOD

(71) Applicant: KABUSHIKI KAISHA TOSHIBA, Tokyo (JP)

(72) Inventors: Tatsuo SHIMIZU, Tokyo (JP); Yukio NAKABAYASHI, Yokohama (JP); Toshihide ITO, Shibuya (JP); Chiharu OTA, Kawasaki (JP); Shigeto FUKATSU, Yokohama (JP); Johji NISHIO, Machida (JP); Ryosuke IIJIMA, Setagaya (JP)

(73) Assignee: KABUSHIKI KAISHA TOSHIBA, Tokyo (JP)

(21) Appl. No.: 17/653,688

(22) Filed: Mar. 7, 2022

(30) Foreign Application Priority Data
Sep. 16, 2021 (JP) 2021-150894

(51) Int. Cl. H01L 21/02; H01L 21/04

(52) U.S. Cl. CPC H01L 21/02236; H01L 21/049; H01L 21/02164

(57) ABSTRACT

A semiconductor device manufacturing method of embodiments includes: forming a silicon oxide film on a surface of a silicon carbide layer; performing a first heat treatment in an atmosphere containing nitrogen gas at a temperature equal to or more than 1200° C. and equal to or less than 1600° C.; and performing a second heat treatment in an atmosphere containing nitrogen oxide gas at a temperature equal to or more than 750° C. and equal to or less than 1050° C.

### CROSS-REFERENCE TO RELATED APPLICATION

This application is based upon and claims the benefit of priority from Japanese Patent Application No. 2021-150894, filed on Sep. 16, 2021, the entire contents of which are incorporated herein by reference.

### FIELD

Embodiments described herein relate generally to a semiconductor device manufacturing method.

### BACKGROUND

Silicon carbide (SiC) is expected as a material for next-generation semiconductor devices. Silicon carbide has excellent physical properties, such as a bandgap of about 3 times, a breakdown field strength of about 10 times, and a thermal conductivity of about 3 times that of silicon (Si). By using such characteristics, it is possible to realize a semiconductor device that can operate at high temperature with low loss.

For example, when a metal oxide semiconductor field effect transistor (MOSFET) is formed using silicon carbide, there is a problem that the mobility of carriers decreases or the threshold voltage fluctuates. One of the factors that cause a decrease in the mobility of carriers or a fluctuation in the threshold voltage is considered to be nitrogen defects or carbon defects present in the gate insulating layer.

### BRIEF DESCRIPTION OF THE DRAWINGS

FIG. 1 is a schematic cross-sectional view of a semiconductor device manufactured by a semiconductor device manufacturing method of a first embodiment;

FIG. 2 is a diagram showing a crystal structure of an SiC semiconductor;

FIG. 3 is a diagram showing an example of the element concentration distribution of the semiconductor device manufactured by the semiconductor device manufacturing method of the first embodiment;

FIGS. 4A and 4B are schematic diagrams showing a bonding state of nitrogen atoms in the semiconductor device manufactured by the semiconductor device manufacturing method of the first embodiment;

FIG. 5 is a process flow diagram of the semiconductor device manufacturing method of the first embodiment;

FIGS. 6A and 6B are explanatory diagrams of nitrogen defects;

FIG. 7 is a process flow diagram of a semiconductor device manufacturing method of a first comparative example;

FIG. 8 is a diagram showing an example of the element concentration distribution of a semiconductor device manufactured by the semiconductor device manufacturing method of the first comparative example;

FIG. 9 is a process flow diagram of a semiconductor device manufacturing method of a second comparative example;

FIG. 10 is a diagram showing an example of the element concentration distribution of a semiconductor device manufactured by the semiconductor device manufacturing method of the second comparative example; and

FIG. 11 is a process flow diagram of a semiconductor device manufacturing method of a second embodiment.

### DETAILED DESCRIPTION

A semiconductor device manufacturing method of embodiments includes: forming a silicon oxide film on a surface of a silicon carbide layer; performing a first heat treatment in an atmosphere containing nitrogen gas at a temperature equal to or more than 1200° C. and equal to or less than 1600° C.; and performing a second heat treatment in an atmosphere containing nitrogen oxide gas at a temperature equal to or more than 750° C. and equal to or less than 1050° C.

Hereinafter, embodiments will be described with reference to the diagrams. In the following description, the same or similar members and the like will be denoted by the same reference numerals, and the description of the members and the like once described will be omitted as appropriate.

In addition, in the following description, when there are notations of n⁺, n, n⁻, p³⁰ , p, and p⁻, these indicate the relative high and low of the impurity concentration in each conductive type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type. Unless otherwise specified, the impurity concentration in each region is represented by, for example, the value of the impurity concentration in the central portion of each region.

The impurity concentration can be measured by, for example, secondary ion mass spectrometry (SIMS). In addition, the relative high and low of the impurity concentration can be determined from, for example, the high and low of the carrier concentration obtained by scanning capacitance microscopy (SCM). In addition, the distance such as the width or depth of an impurity region can be calculated by, for example, SIMS. In addition, the distance such as the width or depth of an impurity region can be calculated from, for example, an SCM image.

The depth of a trench, the thickness of an insulating layer, and the like can be measured, for example, on an image of SIMS or transmission electron microscope (TEM).

The bonding states of silicon atoms, carbon atoms, nitrogen atoms, and oxygen atoms in the silicon carbide layer can be identified by using, for example, X-ray photoelectron spectroscopy (XPS method). In addition, the concentrations of various bonding states and the magnitude relationship between the concentrations can be determined by using, for example, X-ray photoelectron spectroscopy (XPS method).

### First Embodiment

A semiconductor device manufacturing method of a first embodiment includes: forming a silicon oxide film on a surface of a silicon carbide layer; performing a first heat treatment in an atmosphere containing nitrogen gas at a temperature equal to or more than 1200° C. and equal to or less than 1600° C.; and performing a second heat treatment in an atmosphere containing nitrogen oxide gas at a temperature equal to or more than 750° C. and equal to or less than 1050° C.

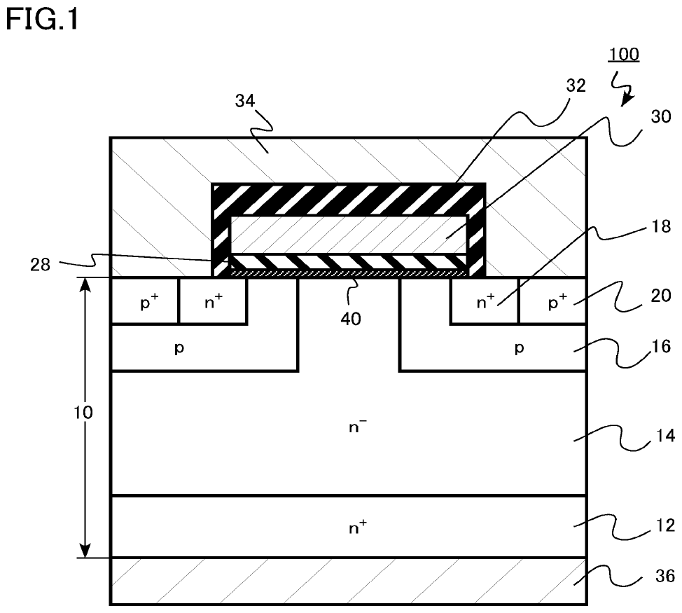

FIG. 1 is a schematic cross-sectional view of a semiconductor device manufactured by the semiconductor device manufacturing method of the first embodiment. The semiconductor device is a MOSFET 100. The MOSFET 100 is a double implantation MOSFET (DIMOSFET) in which a p-well and a source region are formed by ion implantation. In addition, the MOSFET 100 is an n-channel MOSFET having electrons as carriers.

The MOSFET 100 includes a silicon carbide layer 10, a gate insulating layer 28, a gate electrode 30, an interlayer insulating film 32, a source electrode 34, a drain electrode 36, and an interface termination region 40.

The silicon carbide layer 10 includes a drain region 12, a drift region 14, a p-well region 16, a source region 18, and a p-well contact region 20.

The silicon carbide layer 10 is, for example, a single crystal of 4H—SiC. The silicon carbide layer 10 is disposed between the source electrode 34 and the drain electrode 36.

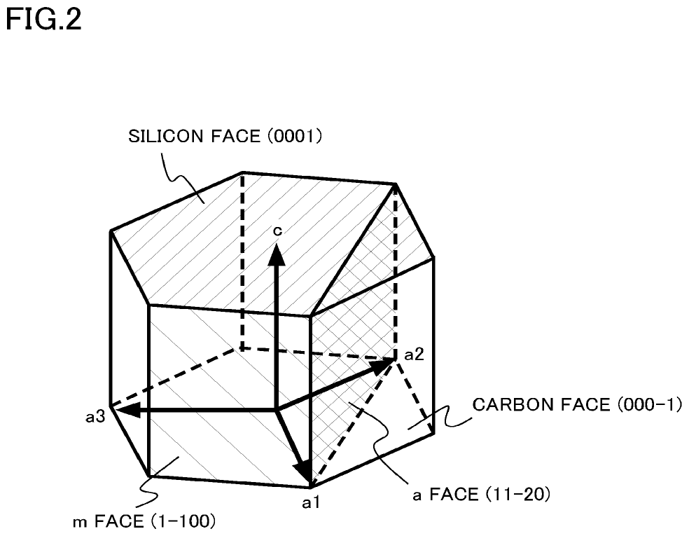

FIG. 2 is a diagram showing the crystal structure of an SiC semiconductor. A typical crystal structure of the SiC semiconductor is a hexagonal system such as 4H—SiC. One of the faces (top surface of the hexagonal column) whose normal line is a c axis along the axial direction of the hexagonal column is a (0001) face. The face equivalent to the (0001) face is referred to as a silicon face (Si face) and denoted as a {0001} face. Silicon atoms (Si) are arranged on the outermost surface of the silicon face.

The other side of the face (top face of the hexagonal column) whose normal line is the c axis along the axial direction of the hexagonal column is a (000-1) face.

The face equivalent to the (000-1) face is referred to as a carbon face (C face) and denoted as a {000-1} face. Carbon atoms (C) are arranged on the outermost surface of the carbon surface.

On the other hand, the side surface (pillar surface) of the hexagonal column is an m face that is a face equivalent to the (1-100) face, that is, a {1-100} face. In addition, the face passing through a pair of ridge lines not adjacent to each other is an a face that is a face equivalent to the (11-20) face, that is, a {11-20} face. Both silicon atoms (Si) and carbon atoms (C) are arranged on the outermost surfaces of the m face and the a face.

Hereinafter, a case where the surface of the silicon carbide layer 10 is a face inclined by an angle equal to or more than 0° and equal to or less than 8° with respect to the silicon face and the back surface of the silicon carbide layer 10 is a face inclined by an angle equal to or more than 0° and equal to or less than 8° with respect to the carbon face will be described as an example. The surface of the silicon carbide layer 10 has an off angle equal to or more than 0° and equal to or less than 8° with respect to the silicon face.

The drain region 12 is an n⁺-type SiC. The drain region 12 contains, for example, nitrogen (N) as an n-type impurity. The n-type impurity concentration in the drain region 12 is, for example, equal to or more than 1×10¹⁸ cm⁻³ and equal to or less than 1×10²¹ cm⁻³.

The drift region 14 is provided on the drain region 12. The drift region 14 is an n⁻-type SiC. The drift region 14 contains, for example, nitrogen as an n-type impurity.

The n-type impurity concentration in the drift region 14 is lower than the n-type impurity concentration in the drain region 12. The n-type impurity concentration in the drift region 14 is, for example, equal to or more than 1×10¹⁵ cm⁻³ and equal to or less than 2×10¹⁶ cm⁻³. The drift region 14 is, for example, a SiC epitaxial growth layer formed on the drain region 12 by epitaxial growth.

The thickness of the drift region 14 is, for example, equal to or more than 5 μm and equal to or less than 100 μm.

The p-well region 16 is provided on a partial surface of the drift region 14. The p-well region 16 is a p-type SiC. The p-well region 16 contains, for example, aluminum (Al) as a p-type impurity. The p-type impurity concentration in the p-well region 16 is, for example, equal to or more than 1×10¹⁶ cm⁻ and equal to or less than 1×10²⁰ cm⁻³.

The depth of the p-well region 16 is, for example, equal to or more than 0.4 μm and equal to or less than 0.8 μm. The p-well region 16 functions as a channel region of the MOSFET 100.

The source region 18 is provided on a partial surface of the p-well region 16. The source region 18 is an n⁺-type SiC. The source region 18 contains, for example, phosphorus (P) as an n-type impurity. The n-type impurity concentration in the source region 18 is, for example, equal to or more than 1×10¹⁸ cm⁻³ and equal to or less than 1×10²² cm⁻³.

The depth of the source region 18 is smaller than the depth of the p-well region 16. The depth of the source region 18 is, for example, equal to or more than 0.2 μm and equal to or less than 0.4 μm.

The p-well contact region 20 is provided on a partial surface of the p-well region 16. The p-well contact region 20 is provided on the side of the source region 18. The p-well contact region 20 is a p⁺-type SiC.

The p-well contact region 20 contains, for example, aluminum as a p-type impurity. The p-type impurity concentration in the p-well contact region 20 is, for example, equal to or more than 1×10¹⁸ cm⁻³ and equal to or less than 1×10²² cm⁻³.

The depth of the p-well contact region 20 is smaller than the depth of the p-well region 16. The depth of the p-well contact region 20 is, for example, equal to or more than 0.2 μm and equal to or less than 0.4 μm.

The gate insulating layer 28 is provided between the silicon carbide layer 10 and the gate electrode 30. The gate insulating layer 28 is provided between the drift region 14 and the p-well region 16 and the gate electrode 30. The gate insulating layer 28 is provided above the drift region 14 and the p-well region 16. The gate insulating layer 28 is continuously formed on the surfaces of the drift region 14 and the p-well region 16.

The gate insulating layer 28 is silicon oxide.

The thickness of the gate insulating layer 28 is, for example, equal to or more than 30 nm and equal to or less than 100 nm. The gate insulating layer 28 functions as a gate insulating layer of the MOSFET 100. The thickness of the gate insulating layer 28 is, for example, equal to or more than 40 nm and equal to or less than 50 nm.

The interface termination region 40 is disposed between the silicon carbide layer 10 and the gate insulating layer 28. The interface termination region 40 is disposed between the drift region 14 and the p-well region 16 and the gate insulating layer 28. The interface termination region 40 contains nitrogen (N) as a termination element for terminating the dangling bond of the silicon carbide layer 10.

The concentration of nitrogen in the interface termination region 40 is, for example, equal to or more than 1×10²¹ cm⁻³.

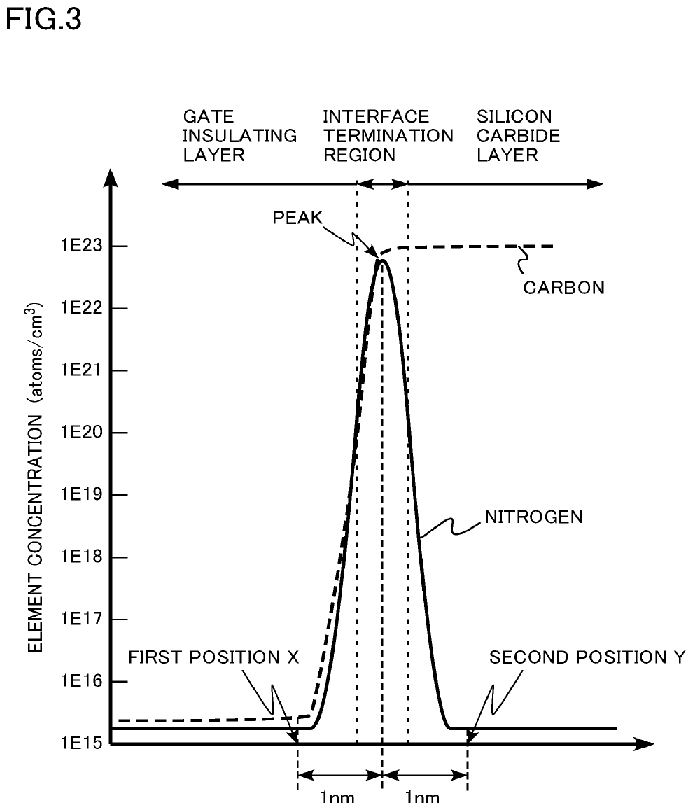

FIG. 3 is a diagram showing an example of the element concentration distribution of the semiconductor device manufactured by the semiconductor device manufacturing method of the first embodiment. FIG. 3 is a diagram showing the element concentration distribution in the gate insulating layer 28, the interface termination region 40, and the silicon carbide layer 10. FIG. 3 shows the concentration distribution of nitrogen and carbon.

The nitrogen concentration distribution has a peak in the interface termination region 40. The peak nitrogen concentration is, for example, equal to or more than 1×10²² cm⁻³. The full width at half maximum with respect to the peak of the nitrogen concentration distribution is, for example, equal to or less than 1 nm. Nitrogen is segregated at the interface between the silicon carbide layer 10 and the gate insulating layer 28.

The nitrogen concentration at a first position X, which is 1 nm away from the peak of the nitrogen concentration distribution toward the gate insulating layer 28, is, for example, equal to or less than 1×10¹⁸ cm⁻³. In addition, the nitrogen concentration at a second position Y, which is 1 nm away from the peak of the nitrogen concentration distribution toward the silicon carbide layer 10, is, for example, equal to or less than 1×10¹⁸ cm⁻³.

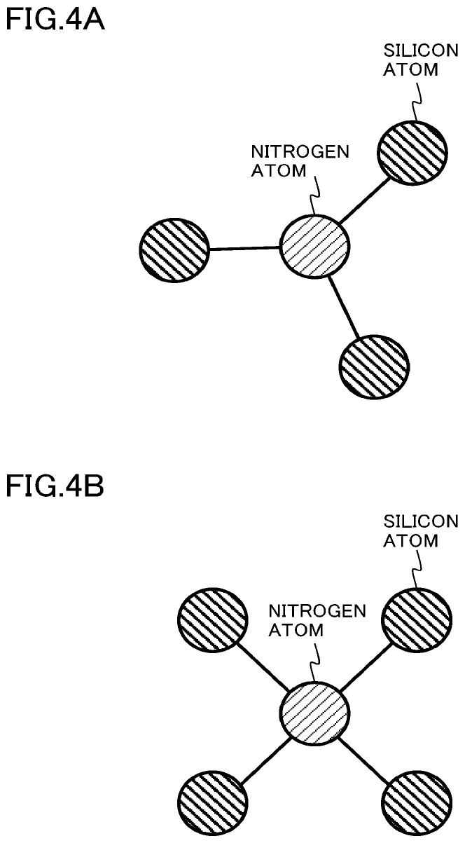

FIGS. 4A and 4B are schematic diagrams showing a bonding state of nitrogen atoms in the semiconductor device manufactured by the semiconductor device manufacturing method of the first embodiment. FIG. 4A shows a case of tri-coordinated nitrogen atom, and FIG. 4B shows a case of four-coordinated nitrogen atom.

In the case of the tri-coordinated nitrogen atom shown in FIG. 4A, the nitrogen atom is bonded to three silicon atoms. In the case of the four-coordinated nitrogen atom shown in FIG. 4B, the nitrogen atom is bonded to four silicon atoms.

In the interface termination region 40, the amount of nitrogen atoms bonded to three silicon atoms is larger than the amount of nitrogen atoms bonded to four silicon atoms. In other words, in the interface termination region 40, the amount of tri-coordinated nitrogen atoms is larger than the amount of four-coordinated nitrogen atoms.

For example, 90% or more of the nitrogen atoms present in the interface termination region 40 are tri-coordinated nitrogen atoms. The concentration of tri-coordinated nitrogen atoms is, for example, equal to or more than 1×10²² cm⁻³.

The tri-coordinated nitrogen atoms present in the interface termination region 40 terminate the dangling bonds on the surface of the silicon carbide layer 10.

The nitrogen atom substitutes the carbon atom of the bilayer forming the uppermost layer of the silicon carbide layer 10. Nitrogen, which is a termination element, is bonded to the silicon carbide layer 10 in a tri-coordinate bond. The nitrogen atom is present at the position of the carbon atom in the crystal structure of silicon carbide. Some of the silicon atoms on the outermost surface of the silicon carbide layer 10 form the gate insulating layer 28, and the nitrogen atom is tri-coordinated with the silicon atoms of the silicon carbide layer 10.

The nitrogen atom present in the bulk of the silicon carbide layer 10 and substituting the carbon site of the crystal structure of silicon carbide is a four-coordinated nitrogen atom. The four-coordinated nitrogen atom becomes an n-type dopant. Therefore, the four-coordinated nitrogen atom lowers the threshold voltage of the MOSFET 100.

The concentration of nitrogen atoms bonded to four silicon atoms at the second position Y is, for example, equal to or less than 1×10¹⁸ cm⁻³. In other words, the concentration of four-coordinated nitrogen atoms at the second position Y is, for example, equal to or less than 1×10¹⁸ cm⁻³.

The carbon concentration distribution decreases from the interface termination region 40 toward the gate insulating layer 28. The carbon concentration at the first position X is, for example, equal to or less than 1×10¹⁸ cm⁻³.

The gate electrode 30 is provided on the gate insulating layer 28. The gate insulating layer 28 is interposed between the gate electrode 30 and the silicon carbide layer 10. The gate insulating layer 28 is interposed between the gate electrode 30 and the drift region 14. The gate insulating layer 28 is interposed between the gate electrode 30 and the p-well region 16.

The gate electrode 30 is, for example, polycrystalline silicon containing n-type impurities or p-type impurities.

The interlayer insulating film 32 is formed on the gate electrode 30. The interlayer insulating film 32 is, for example, a silicon oxide film.

The source electrode 34 is electrically connected to the source region 18 and the p-well contact region 20. The source electrode 34 also functions as a p-well electrode for applying an electric potential to the p-well region 16.

The source electrode 34 has, for example, a stacked structure of a barrier metal layer of nickel (Ni) and a metal layer of aluminum on the barrier metal layer. The barrier metal layer of nickel and the silicon carbide layer may react with each other to form nickel silicide. The nickel silicide is, for example, NiSi or Ni₂Si. The barrier metal layer formed of nickel and the metal layer formed of aluminum may form an alloy by reaction.

The drain electrode 36 is provided on a side of the silicon carbide layer 10 opposite to the source electrode 34, that is, on the back surface side of the silicon carbide layer 10. The drain electrode 36 is, for example, nickel. Nickel may react with the drain region 12 to form nickel silicide. The nickel silicide is, for example, NiSi or Ni₂Si.

In addition, in the MOSFET 100 of the first embodiment, the n-type impurity is, for example, nitrogen or phosphorus. Arsenic (As) or antimony (Sb) can also be applied as an n-type impurity.

In addition, in the MOSFET 100 of the first embodiment, the p-type impurity is, for example, aluminum. Boron (B), gallium (Ga), and indium (In) can also be applied as p-type impurities.

Next, a semiconductor device manufacturing method of the first embodiment will be described.

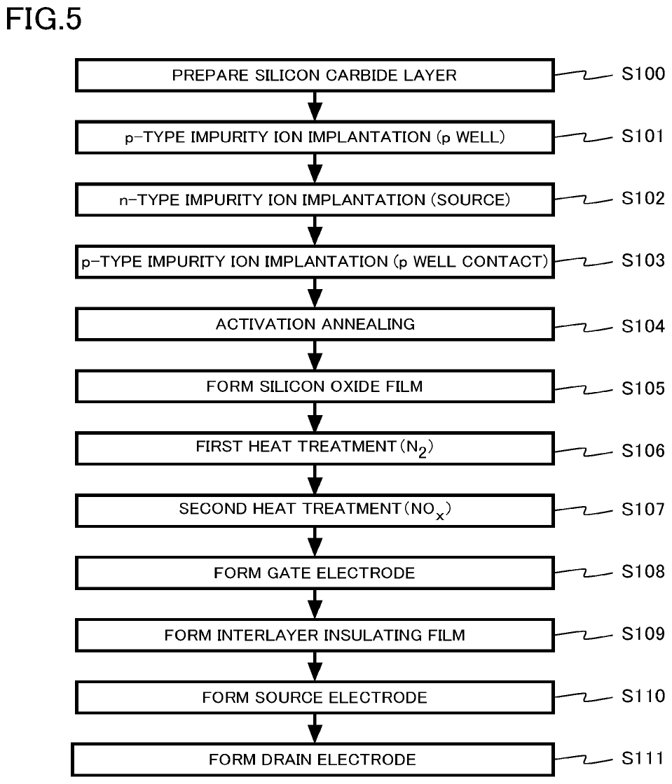

FIG. 5 is a process flow diagram of the semiconductor device manufacturing method of the first embodiment.

As shown in FIG. 5, the semiconductor device manufacturing method of the first embodiment includes silicon carbide layer preparation (step S100), p-type impurity ion implantation (step S101), n-type impurity ion implantation (step S102), p-type impurity ion implantation (step S103), activation annealing (step S104), silicon oxide film formation (step S105), first heat treatment (step S106), second heat treatment (step S107), gate electrode formation (step S108), interlayer insulating film formation (step S109), source electrode formation (step S110), and drain electrode formation (step S111).

In step 5100, the silicon carbide layer 10 is prepared. The silicon carbide layer 10 includes an n⁺-type drain region 12 and an n⁻-type drift region 14. The drift region 14 is formed, for example, on the drain region 12 by an epitaxial growth method.

The drain region 12 contains nitrogen as an n-type impurity. The n-type impurity concentration in the drain region 12 is, for example, equal to or more than 1×10¹⁸ cm⁻³ and equal to or less than 1×10²¹ cm⁻³.

The drift region 14 contains nitrogen as an n-type impurity. The n-type impurity concentration in the drift region 14 is, for example, equal to or more than 1×10¹⁵ cm⁻³ and equal to or less than 2×10¹⁶ cm⁻³. The thickness of the drift region 14 is, for example, equal to or more than 5 μm and equal to or less than 100 μm.

In step S101, first, a first mask material is formed by patterning using photolithography and etching.

Then, by using the first mask material as an ion implantation mask, aluminum (Al), which is a p-type impurity, is ion-implanted into the drift region 14. By the ion implantation, the p-well region 16 is formed.

In step S102, first, a second mask material is formed by patterning using photolithography and etching. Then, by using the second mask material as an ion implantation mask, phosphorus (P), which is an n-type impurity, is ion-implanted into the drift region 14 to form the source region 18.

In step S103, first, a third mask material is formed by patterning using photolithography and etching. By using the third mask material as an ion implantation mask, aluminum (Al), which is a p-type impurity, is ion-implanted into the drift region 14 to form the p-well contact region 20.

Then, a carbon film is formed on the surface of the silicon carbide layer 10. The carbon film is formed by using, for example, a sputtering method. The carbon film suppresses the surface of the silicon carbide layer 10 from being roughened during the subsequent activation annealing.

In step S104, activation annealing is performed. By the activation annealing, p-type impurities and n-type impurities ion-implanted into the silicon carbide layer 10 are activated. The activation annealing is performed, for example, in an argon atmosphere. The temperature of the activation annealing is, for example, equal to or more than 1600° C. and equal to or less than 1800° C.

Then, the carbon film on the surface of the silicon carbide layer 10 is removed. The carbon film is removed, for example, by an asking treatment using oxygen plasma.

In step S105, a silicon oxide film is formed on the surface of the silicon carbide layer 10. The silicon oxide film finally becomes the gate insulating layer 28.

The silicon oxide film is formed by, for example, vapor phase growth. The silicon oxide film is formed by using, for example, a chemical vapor deposition method (CVD method) or a physical vapor deposition method (PVD method). The silicon oxide film is a sedimentary film. The thickness of the silicon oxide film is, for example, equal to or more than 30 nm and equal to or less than 100 nm. The thickness of the silicon oxide film is, for example, equal to or more than 40 nm and equal to or less than 50 nm.

The silicon oxide film is, for example, a silicon oxide film formed by a CVD method using tetraethyl orthosilicate (TEOS) as a source gas. In addition, the silicon oxide film is, for example, a silicon oxide film formed by a CVD method using dichlorosilane gas (SiH₂Cl₂) and nitrous oxide gas (N₂O) as source gases.

The silicon oxide film is formed at a temperature equal to or less than 600° C., for example.

In step S106, a first heat treatment is performed. The first heat treatment is performed in an atmosphere containing nitrogen gas (N₂).

The partial pressure of the nitrogen gas in the atmosphere of the first heat treatment is, for example, equal to or more than 99%.

The partial pressure of the oxygen-containing gas in the atmosphere of the first heat treatment is, for example, equal to or less than 10 ppm. The partial pressure of the oxygen gas in the atmosphere of the first heat treatment is, for example, equal to or less than 10 ppm.

For example, a nitrogen gas (N₂) is supplied to the reaction furnace containing the silicon carbide layer 10 to perform the first heat treatment. In the first heat treatment, the oxygen-containing gas is not positively supplied to the reaction furnace.

The temperature of the first heat treatment is, for example, equal to or more than 1200° C. and equal to or less than 1600° C.

By the first heat treatment, the interface termination region 40 containing nitrogen is formed at the interface between the silicon carbide layer 10 and the silicon oxide film.

The first heat treatment also functions as densify annealing of the silicon oxide film. By the first heat treatment, the silicon oxide film becomes a high-density film.

For the first heat treatment, for example, a mixed gas of nitrogen gas and inert gas can be used. For the first heat treatment, for example, a mixed gas of nitrogen gas and argon gas can be used.

In step S107, a second heat treatment is performed. The second heat treatment is performed in an atmosphere containing nitrogen oxide gas (NOx). The nitrogen oxide gas is, for example, a nitric oxide gas (NO). In addition, the nitrogen oxide gas is, for example, a nitrous oxide gas (N₂O).

For example, the nitrogen oxide gas (NOx) is supplied to a reaction furnace containing the silicon carbide layer 10 to perform second heat treatment.

The temperature of the second heat treatment is equal to or more than 750° C. and equal to or less than 1050° C. The temperature of the second heat treatment is lower than the temperature of the first heat treatment.

The partial pressure of the nitrogen oxide gas in the atmosphere of the second heat treatment is, for example, equal to or more than 10%.

By the second heat treatment, nitrogen in the silicon oxide film is removed. By the second heat treatment, a silicon oxide film with reduced nitrogen defects is formed.

In step S108, the gate electrode 30 is formed on the gate insulating layer 28. The gate electrode 30 is, for example, polycrystalline silicon containing n-type impurities or p-type impurities.

In step S109, the interlayer insulating film 32 is formed on the gate electrode 30. The interlayer insulating film 32 is, for example, a silicon oxide film.

In step S110, the source electrode 34 is formed.

The source electrode 34 is formed on the source region 18 and the p-well contact region 20. The source electrode 34 is formed, for example, by sputtering nickel (Ni) and aluminum (Al).

In step S111, the drain electrode 36 is formed. The drain electrode 36 is formed on the back surface side of the silicon carbide layer 10. The drain electrode 36 is formed, for example, by sputtering nickel.

By the manufacturing method described above, the MOSFET 100 shown in FIG. 1 is formed.

Next, the function and effect of the semiconductor device manufacturing method of the first embodiment will be described.

The MOSFET 100 manufactured by the semiconductor device manufacturing method of the first embodiment includes the interface termination region 40 having a high nitrogen concentration. The interface termination region 40 is formed by the first heat treatment (step S106) performed in an atmosphere containing nitrogen gas (N₂). Therefore, according to the semiconductor device manufacturing method of the first embodiment, a MOSFET in which a decrease in the mobility of carriers is suppressed is realized.

In addition, in the MOSFET 100 manufactured by the semiconductor device manufacturing method of the first embodiment, the amount of nitrogen defects and carbon defects in the gate insulating layer 28 is reduced. The amount of nitrogen defects in the gate insulating layer 28 is reduced by the second heat treatment (step S107) performed in an atmosphere containing nitrogen oxide gas (NOx). In addition, the amount of carbon defects in the gate insulating layer 28 is reduced by using the first heat treatment (step S106), which is performed in an atmosphere containing nitrogen gas (N₂), for forming the interface termination region 40. Therefore, a MOSFET is realized in which a decrease in the mobility of carriers, a decrease in the threshold voltage, a fluctuation in the threshold voltage, an increase in the leakage current of the gate insulating layer, or a decrease in the reliability of the gate insulating layer due to nitrogen defects or carbon defects in the gate insulating layer 28 is suppressed.

The details will be described below.

When a MOSFET is formed using silicon carbide, there is a problem that the mobility of carriers decreases. One factor that decreases the mobility of carriers is considered to be the interface state between the silicon carbide layer and the gate insulating layer. It is considered that the interface state is caused by the dangling bonds present on the surface of the silicon carbide layer.

In addition, when a MOSFET is formed using silicon carbide, there is a problem that the mobility of carriers decreases or the threshold voltage fluctuates. In addition, there is a problem that the leakage current of the gate insulating layer increases and the reliability of the gate insulating layer decreases. One factor that causes the above-described problems is considered to be nitrogen defects or carbon defects present in the gate insulating layer.

Nitrogen defects or carbon defects are considered to be factors that cause the above-described problems by forming trap levels in the gate insulating layer.

There are various forms of nitrogen defects in the insulating layer.

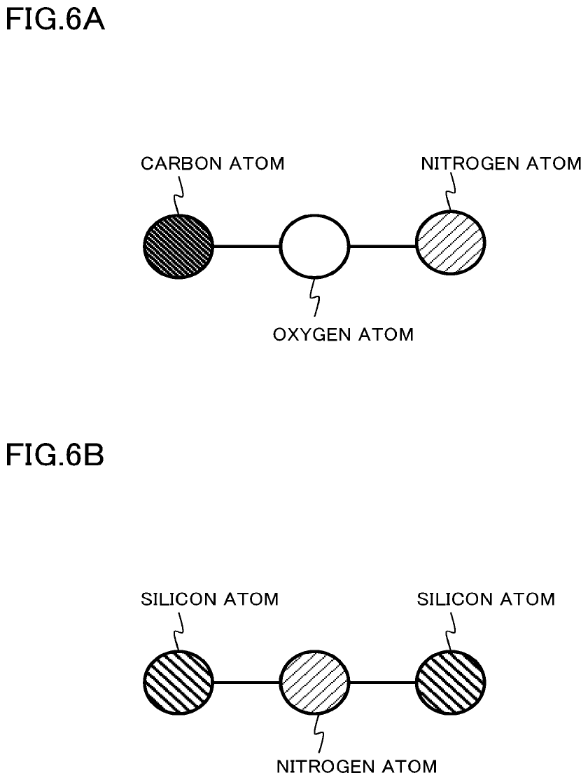

FIGS. 6A and 6B are explanatory diagrams of nitrogen defects. FIG. 6A shows a complex containing a carbon atom bonded to an oxygen atom and a nitrogen atom bonded to the oxygen atom. FIG. 6A shows a C—O—N bond. The carbon atom and the nitrogen atom of the C—O—N bond are present in the silicon site of silicon oxide.

FIG. 6B shows a nitrogen defect having a structure in which a nitrogen atom is bonded to at least two silicon atoms. In the nitrogen defect of FIG. 6B, a nitrogen atom is present in the oxygen site of silicon oxide.

There are various forms of carbon defects. For example, there are a double bond between carbon atoms, a tri-coordinated carbon in which three silicon atoms are coordinated, and a structure in which an oxygen atom is double-bonded to a carbon atom. It has been clarified by the first principle calculation of the inventors that these carbon defects form trap levels due to the Pz orbit. These carbon defects are formed by the entry of carbon atoms into the oxygen sites of silicon oxide.

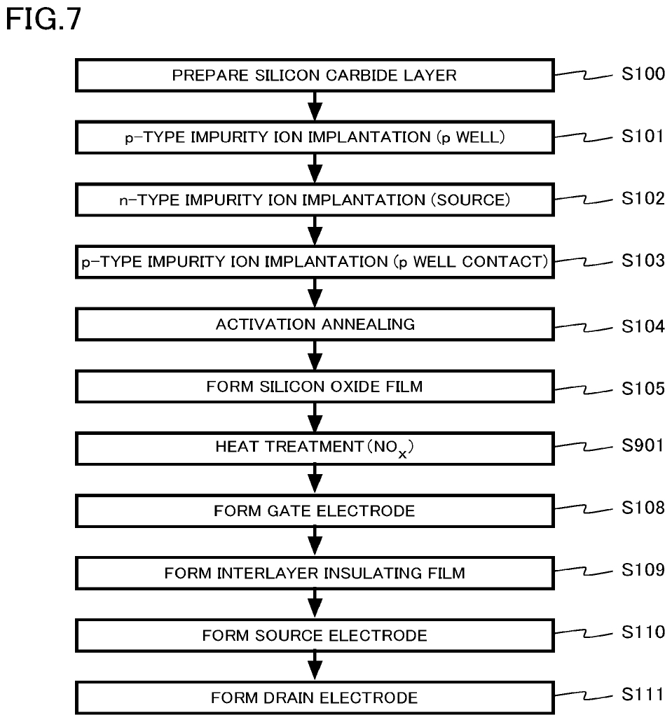

FIG. 7 is a process flow diagram of a semiconductor device manufacturing method of a first comparative example. In the semiconductor device manufacturing method of the first comparative example, the first heat treatment (step S106) of the semiconductor device manufacturing method of the first embodiment is omitted. In addition, instead of the second heat treatment (step S107), heat treatment (step S901) is performed.

Similar to the second heat treatment (step S107), the heat treatment in step S901 is performed in an atmosphere containing nitrogen oxide gas (NOx). The nitrogen oxide gas is, for example, a nitric oxide gas (NO). In addition, the nitrogen oxide gas is, for example, a nitrous oxide gas (N₂O).

The heat treatment (step S901) is a heat treatment at a higher temperature than the second heat treatment (step S107). The temperature of the heat treatment is, for example, equal to or more than 1100° C. and equal to or less than 1450° C.

By the heat treatment in step S901, an interface termination region containing nitrogen is formed at the interface between the silicon carbide layer and the silicon oxide film.

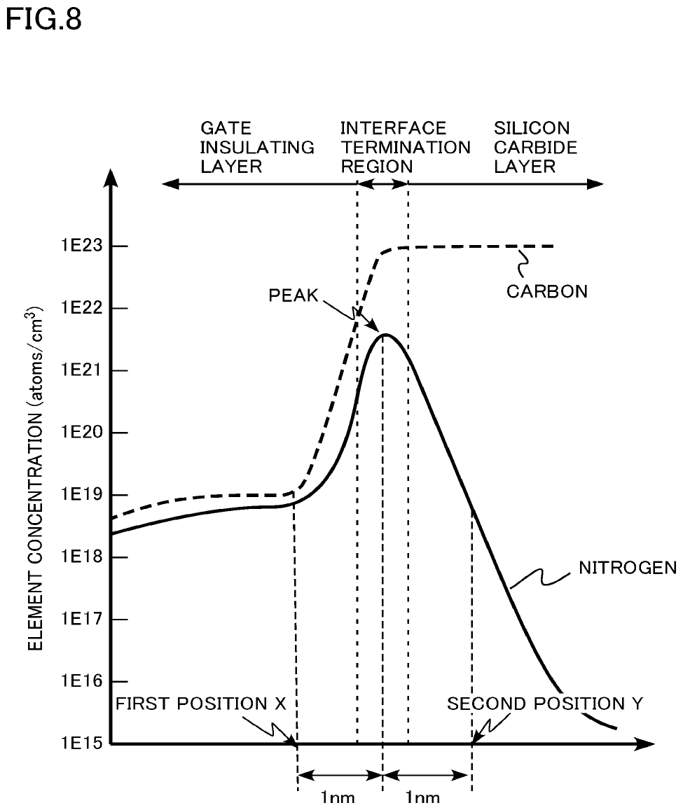

FIG. 8 is a diagram showing an example of the element concentration distribution of a semiconductor device manufactured by the semiconductor device manufacturing method of the first comparative example. The semiconductor device manufactured by the semiconductor device manufacturing method of the first comparative example is a MOSFET manufactured by the semiconductor device manufacturing method shown in FIG. 7.

FIG. 8 is a diagram showing the element concentration distribution in the gate insulating layer, the interface termination region, and the silicon carbide layer. FIG. 8 shows the concentration distribution of nitrogen and carbon.

The nitrogen concentration distribution has a peak in the interface termination region. The peak nitrogen concentration is, for example, equal to or more than 1×10²¹ cm⁻³ and less than 1×10²² cm⁻³. Nitrogen is segregated at the interface between the silicon carbide layer and the gate insulating layer.

In the high-temperature heat treatment (step S901) in the atmosphere containing the nitrogen oxide gas of the first comparative example, oxidation and nitriding of the surface of the silicon carbide layer occur at the same time. Due to the oxidation, the interface between the silicon oxide film and the silicon carbide layer moves to the silicon carbide layer side. For this reason, the nitrogen concentration in the interface termination region does not increase, and the nitrogen concentration is suppressed to less than 1×10²² cm⁻³. When the nitrogen concentration is less than 1×10²² cm⁻³, the interface state may remain at the interface, resulting in degradation of the mobility of carriers.

The MOSFET of the first comparative example has a high nitrogen concentration in the gate insulating layer. For example, as shown in FIG. 8, the nitrogen concentration at the first position X, which is 1 nm away from the peak of the nitrogen concentration distribution toward the gate insulating layer, is higher than 1×10¹⁸ cm⁻³.

The nitrogen in the gate insulating layer is derived from the nitrogen oxide gas in the heat treatment (step S901). Nitrogen in the gate insulating layer forms nitrogen defects.

The MOSFET of the first comparative example has a high carbon concentration in the gate insulating layer. For example, as shown in FIG. 8, the carbon concentration at the first position X, which is 1 nm away from the peak of the nitrogen concentration distribution toward the gate insulating layer, is higher than 1×10¹⁸ cm⁻³.

It is considered that the carbon in the gate insulating layer is derived from the carbon emitted from the silicon carbide layer when the surface of the silicon carbide layer is oxidized by the heat treatment (step S901). In addition, it is considered that the nitrogen of the nitrogen oxide gas is bonded to the carbon emitted from the silicon carbide layer to form a C—O—N bond and accordingly remains in the gate insulating layer. The carbon in the gate insulating layer forms carbon defects.

The problem of the MOSFET of the first comparative example is a decrease in the mobility of carriers, a decrease in the threshold voltage, a fluctuation in the threshold voltage, an increase in the leakage current of the gate insulating layer, or a decrease in the reliability of the gate insulating layer due to traps caused by nitrogen defects or carbon defects in the gate insulating layer.

The MOSFET of the first comparative example has a high nitrogen concentration in the silicon carbide layer. For example, as shown in FIG. 8, the nitrogen concentration at the second position Y, which is 1 nm away from the peak of the nitrogen concentration distribution toward the silicon carbide layer, is higher than 1×10¹⁸ cm⁻³.

In the heat treatment (step S901), the surface of the silicon carbide layer is oxidized, and carbon in the silicon carbide layer is removed to generate carbon vacancies. Nitrogen atoms enter the generated carbon vacancies. Since the nitrogen atom entering the carbon vacancy functions as an n-type dopant, the threshold voltage of the MOSFET is reduced.

As described above, the problem of the MOSFET manufactured by the semiconductor device manufacturing method of the first comparative example is a decrease in the mobility of carriers, a decrease in the threshold voltage, a fluctuation in the threshold voltage, an increase in the leakage current of the gate insulating layer, or a decrease in the reliability of the gate insulating layer due to the interface state remaining due to the insufficient nitrogen concentration in the interface termination region and the traps caused by nitrogen defects or carbon defects in the gate insulating layer.

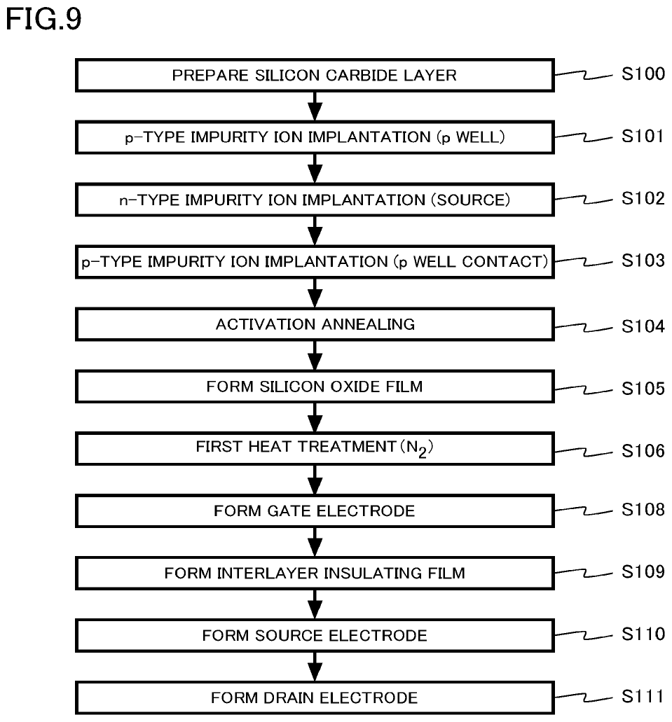

FIG. 9 is a process flow diagram of a semiconductor device manufacturing method of a second comparative example. In the semiconductor device manufacturing method of the second comparative example, the second heat treatment (S107) in the semiconductor device manufacturing method of the first embodiment is omitted.

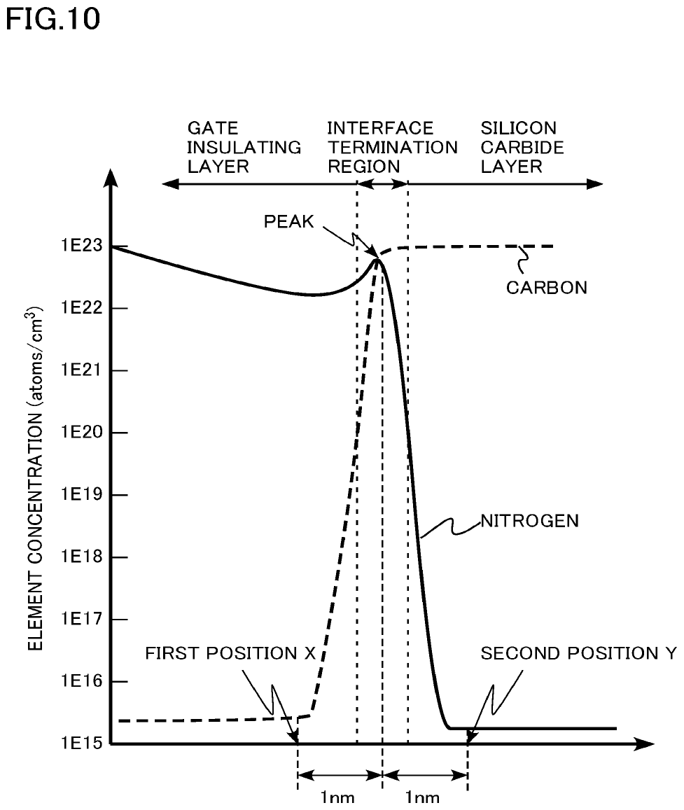

FIG. 10 is a diagram showing an example of the element concentration distribution of a semiconductor device manufactured by the semiconductor device manufacturing method of the second comparative example. The semiconductor device manufactured by the semiconductor device manufacturing method of the second comparative example is a MOSFET manufactured by the semiconductor device manufacturing method shown in FIG. 9.

FIG. 10 is a diagram showing the element concentration distribution in the gate insulating layer, the interface termination region, and the silicon carbide layer. FIG. 10 shows the concentration distribution of nitrogen and carbon.

The nitrogen concentration distribution has a peak in the interface termination region. The peak nitrogen concentration is, for example, equal to or more than 1×10²² cm⁻³. Nitrogen is segregated at the interface between the silicon carbide layer and the gate insulating layer.

By performing the first heat treatment (step S106) in a nitrogen gas atmosphere, the nitrogen concentration in the interface termination region can be made higher than that in the semiconductor device manufacturing method of the first comparative example. This is because the first heat treatment (step S106) is performed in a nitrogen gas atmosphere containing no oxygen and accordingly, the oxidation of the surface of the silicon carbide layer is suppressed. Therefore, in the MOSFET of the second comparative example, the decrease in the mobility of carriers due to the interface state is suppressed as compared with the MOSFET of the first comparative example.

The MOSFET of the second comparative example has a higher nitrogen concentration in the gate insulating layer than the MOSFET of the first comparative example. The nitrogen concentration at the first position X, which is 1 nm away from the peak of the nitrogen concentration distribution toward the gate insulating layer, is higher than, for example, 1×10¹⁸ cm⁻³. In particular, a large amount of nitrogen is distributed throughout the film. For example, the nitrogen concentration is equal to or more than 1×10²² cm⁻³.

The MOSFET of the second comparative example has a very high nitrogen concentration in the gate insulating layer as compared with the MOSFET of the first comparative example. In the semiconductor device manufacturing method of the second comparative example, the nitrogen concentration in the atmosphere during the first heat treatment (step S106) is higher than that in the heat treatment (step S901) of the semiconductor device manufacturing method of the first comparative example. Therefore, the nitrogen concentration in the gate insulating layer increases. Nitrogen in the gate insulating layer forms nitrogen defects.

The MOSFET of the second comparative example has a low carbon concentration in the gate insulating layer. For example, as shown in FIG. 10, the carbon concentration at the first position X, which is 1 nm away from the peak of the nitrogen concentration distribution toward the gate insulating layer, is lower than 1×10¹⁰ cm⁻³. The carbon concentration distribution decreases from the interface termination region toward the gate insulating layer.

In the semiconductor device manufacturing method of the second comparative example, the surface of the silicon carbide layer is not oxidized and carbon is not emitted from the silicon carbide layer. For this reason, the carbon concentration in the gate insulating layer is lower than that in the MOSFET of the first comparative example.

Therefore, the MOSFET of the second comparative example has less carbon defects in the gate insulating layer than the MOSFET of the first comparative example. In addition, since the carbon concentration in the gate insulating layer is low, nitrogen defects having C—O—N bonds are also reduced as compared with the MOSFET of the first comparative example.

Therefore, in the MOSFET of the second comparative example, the problem of the decrease in the mobility of carriers, the fluctuation in the threshold voltage, the increase in the leakage current of the gate insulating layer, or the decrease in the reliability of the gate insulating layer due to the carbon defects in the gate insulating layer or the nitrogen defects having C—O—N bonds is suppressed as compared with the MOSFET of the first comparative example. However, the problem of the decrease in the mobility of carriers, the decrease in the threshold voltage, the fluctuation in the threshold voltage, the increase in the leakage current of the gate insulating layer, or the decrease in the reliability of the gate insulating layer due to the nitrogen defects in the gate insulating layer becomes worse than the MOSFET of the first comparative example.

The MOSFET of the second comparative example has a low nitrogen concentration in the silicon carbide layer. For example, as shown in FIG. 10, the nitrogen concentration at the second position Y, which is 1 nm away from the peak of the nitrogen concentration distribution toward the silicon carbide layer, is lower than 1×10¹⁸ cm⁻³.

In the semiconductor device manufacturing method of the second comparative example, an oxidizing gas is not used for forming the interface termination region. Therefore, the surface of the silicon carbide layer is not oxidized and carbon is not emitted from the silicon carbide layer.

Therefore, in the semiconductor device manufacturing method of the second comparative example, the formation of carbon vacancies in the silicon carbide layer is suppressed and the nitrogen concentration in the silicon carbide layer is reduced as compared with the semiconductor device manufacturing method of the first comparative example. As a result, the decrease in the threshold voltage of the MOSFET of the second comparative example is suppressed.

As described above, in the semiconductor device manufacturing method of the second comparative example, the nitrogen concentration in the interface termination region can be increased as compared with the semiconductor device manufacturing method of the first comparative example. In addition, carbon defects and nitrogen defects having C—O—N bonds in the gate insulating layer can be reduced. However, the amount of nitrogen defects in the gate insulating layer is high. Therefore, the decrease in the mobility of carriers, the decrease in the threshold voltage, the fluctuation in the threshold voltage, the increase in the leakage current of the gate insulating layer, or the decrease in the reliability of the gate insulating layer due to nitrogen defects in the gate insulating layer becomes a problem.

In the semiconductor device manufacturing method of the first embodiment, after the silicon oxide film is formed in step S105, the first heat treatment is performed in step S106. The first heat treatment is performed in an atmosphere containing nitrogen gas (N₂).

The element concentration distribution immediately after the interface termination region 40 is formed by the first heat treatment is the same as the element concentration distribution of the MOSFET of the second comparative example shown in FIG. 10.

Immediately after the first heat treatment in step S106, the nitrogen concentration in the silicon oxide film is high. Nitrogen in the silicon oxide film forms, for example, a nitrogen defect having a structure in which a nitrogen atom is bonded to at least two silicon atoms. In this nitrogen defect, the nitrogen atom substitutes the oxygen site of silicon oxide.

In the semiconductor device manufacturing method of the first embodiment, after the first heat treatment, the second heat treatment is performed in step S107. The second heat treatment is performed in an atmosphere containing nitrogen oxide gas (NOx).

The inclusion of nitrogen oxide gas (NOx) in the atmosphere of the second heat treatment reduces nitrogen defects in the silicon oxide film. It is considered that the nitrogen atom substituting the oxygen site of silicon oxide is substituted by the oxygen atom of nitrogen oxide gas (NOx) and the nitrogen atom becomes nitrogen gas (N₂) to be emitted from the silicon oxide film.

Therefore, the second heat treatment reduces nitrogen defects in the silicon oxide film and reduces the nitrogen concentration in the silicon oxide film.

The temperature of the second heat treatment is equal to or less than 1050° C. Since the temperature of the second heat treatment is low, the progress of the oxidation of the surface of the silicon carbide layer 10 by the second heat treatment is suppressed. Therefore, due to the second heat treatment, an increase in the carbon concentration in the silicon oxide film is suppressed. In addition, nitrogen that has contributed to the interface termination is diffused into the silicon oxide film, so that a decrease in the nitrogen concentration in the interface termination region is suppressed. That is, the nitrogen concentration in the interface termination region is maintained.

In the MOSFET 100 manufactured by the semiconductor device manufacturing method of the first embodiment, as shown in FIG. 3, the nitrogen concentration in the interface termination region 40 is high as in the MOSFET of the second comparative example. Therefore, the decrease in the mobility of carriers is suppressed.

In addition, in the MOSFET 100 manufactured by the semiconductor device manufacturing method of the first embodiment, as shown in FIG. 3, the nitrogen concentration or the carbon concentration in the gate insulating layer 28 is lower than that in the MOSFET of the first comparative example. In addition, the nitrogen concentration in the gate insulating layer 28 is lower than that in the MOSFET of the second comparative example. Therefore, the amount of carbon defects and nitrogen defects in the gate insulating layer 28 is smaller than that in the MOSFET of the first comparative example and the MOSFET of the second comparative example.

Therefore, in the MOSFET 100 of the first embodiment, the decrease in the mobility of carriers, the decrease in the threshold voltage, the fluctuation in the threshold voltage, the increase in the leakage current of the gate insulating layer, or the decrease in the reliability of the gate insulating layer due to nitrogen defects and carbon defects in the gate insulating layer is suppressed.

According to the semiconductor device manufacturing method of the first embodiment, it is possible to realize the MOSFET 100 in which the nitrogen concentration in the interface termination region 40 is high and the amount of nitrogen defects and carbon defects in the gate insulating layer 28 is reduced.

The temperature of the first heat treatment is preferably equal to or more than 1300° C., more preferably equal to or more than 1400° C. By raising the temperature of the first heat treatment, the nitrogen concentration in the interface termination region 40 can be further increased.

The partial pressure of the nitrogen gas in the atmosphere of the first heat treatment is preferably equal to or more than 99%, more preferably equal to or more than 99.9%, and even more preferably 100%. By increasing the partial pressure of the nitrogen gas in the atmosphere of the first heat treatment, the nitrogen concentration in the interface termination region 40 can be further increased.

The time of the first heat treatment is preferably equal to or more than one hour, more preferably equal to or more than two hours. By increasing the time of the first heat treatment, the nitrogen concentration in the interface termination region 40 can be further increased. On the other hand, the increase in the time of the first heat treatment increases the amount of nitrogen defects in the gate insulating layer 28. That is, by increasing the time of the first heat treatment, the nitrogen concentration in the interface termination region 40 can be increased, but the amount of nitrogen defects in the gate insulating layer 28 is increased. It is not possible to achieve both the increase in the nitrogen concentration in the interface termination region 40 and the decrease in the nitrogen concentration in the gate insulating layer simply by adjusting the time of the first heat treatment. By the second heat treatment, it is possible to remove the nitrogen defects in the film while maintaining the interface termination. Therefore, it is possible to reduce the nitrogen concentration in the gate insulating layer while maintaining the increase in the nitrogen concentration in the interface termination region 40 due to the increase in the time of the first heat treatment.

The temperature of the second heat treatment is preferably equal to or more than 800° C., more preferably equal to or more than 850° C., and even more preferably equal to or more than 925° C. By raising the temperature of the second heat treatment, nitrogen defects in the silicon oxide film can be further reduced.

The second heat treatment is preferably performed at 950° C. for 30 minutes or more, more preferably performed at 950° C. for one hour or more, and even more preferably performed at 950° C. for two hours or more. By performing the heat treatment under the above conditions, the nitrogen concentration in the silicon oxide film can be further reduced.

In addition, the temperature of the second heat treatment is preferably equal to or less than 1000° C., more preferably equal to or less than 950° C. By lowering the temperature of the second heat treatment, the oxidation of the silicon carbide layer 10 can be further suppressed.

The nitrogen oxide gas in the second heat treatment is preferably a nitrous oxide gas (N₂O) having high oxidizing power. By using the nitrogen oxide gas having high oxidizing power, nitrogen defects in the silicon oxide film can be further reduced.

In the semiconductor device manufacturing method of the first embodiment, the silicon oxide film formed in step S105 is preferably formed by vapor phase growth. By forming the silicon oxide film by using the vapor phase growth instead of thermal oxidation, the oxidation of the silicon carbide layer can be further suppressed. Therefore, the carbon concentration in the silicon oxide film can be further reduced.

The silicon oxide film is preferably formed at a temperature equal to or less than 600° C., more preferably formed at a temperature equal to or less than 500° C., and even more preferably formed at a temperature equal to or less than 450° C. By forming the silicon oxide film at a low temperature, the oxidation of the surface of the silicon carbide layer is suppressed, and the carbon concentration in the silicon oxide film is further reduced.

The silicon oxide film formed in step S105 preferably has a silicon oxide film whose entire film is rich in silicon by lowering the oxygen partial pressure during growth. As SiO_{2-δ}, 0.01≤δ≤0.1 is preferable. That is, it is preferable to make an adjustment so that the oxygen deficiency is equal to or more than 0.5% and equal to or less than 5%. This is because, if there is excess oxygen in the silicon oxide film during the first heat treatment, there is a risk of substrate oxidation during high-temperature treatment and accordingly, it is preferable to have no excess oxygen. By performing the second heat treatment, oxygen is supplied to the oxygen deficiency in the insulating film, so that a good silicon oxide film having no oxygen deficiency is finally obtained.

As described above, according to the first embodiment, a semiconductor device manufacturing method is realized in which the nitrogen concentration in the interface termination region is high and the amount of nitrogen defects and carbon defects in the insulating layer is reduced.

### Second Embodiment

A semiconductor device manufacturing method of a second embodiment is different from the semiconductor device manufacturing method of the first embodiment in that the silicon carbide layer is subjected to a third heat treatment at a first temperature in an atmosphere containing hydrogen gas before the silicon oxide film is formed. In addition, the semiconductor device manufacturing method of the second embodiment is different from the semiconductor device manufacturing method of the first embodiment in that the silicon carbide layer is subjected to a fourth heat treatment at a second temperature in an atmosphere containing hydrogen gas before the first heat treatment after the silicon oxide film is formed. In addition, the semiconductor device manufacturing method of the second embodiment is different from the semiconductor device manufacturing method of the first embodiment in that aluminum (Al) and carbon (C) are ion-implanted into the silicon carbide layer before the silicon oxide film is formed. Hereinafter, the description of a part of the content overlapping the first embodiment will be omitted.

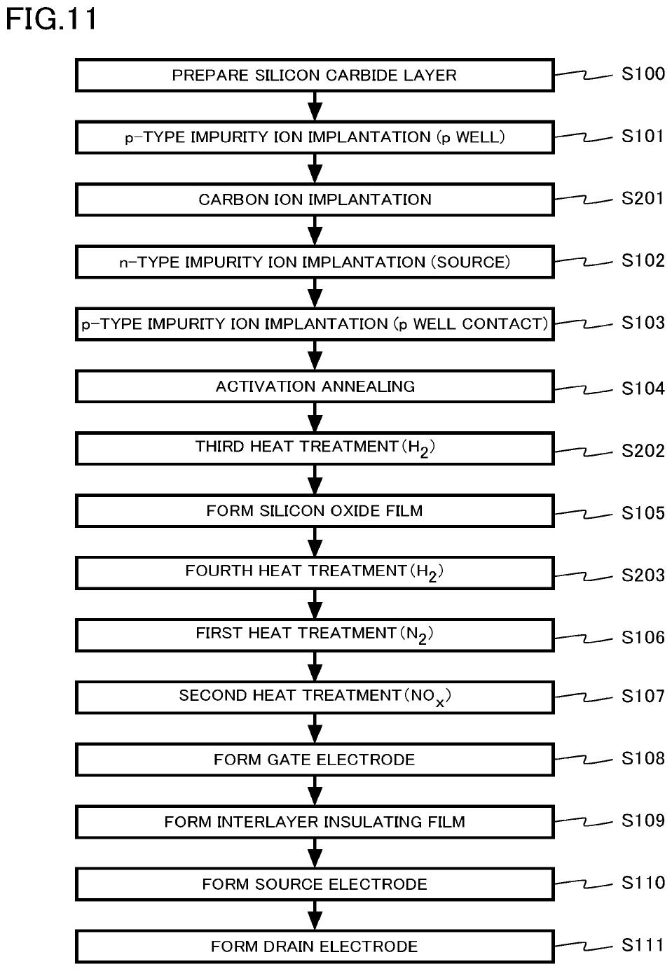

FIG. 11 is a process flow diagram of the semiconductor device manufacturing method of the second embodiment. The MOSFET 100 shown in FIG. 1 is formed by the semiconductor device manufacturing method of the second embodiment.

As shown in FIG. 11, the semiconductor device manufacturing method of the second embodiment includes silicon carbide layer preparation (step S100), p-type impurity ion implantation (step S101), carbon ion implantation (step S201), n-type impurity ion implantation (step S102), p-type impurity ion implantation (step S103), activation annealing (step S104), third heat treatment (step S202), silicon oxide film formation (step S105), fourth heat treatment (step S203), first heat treatment (step S106), second heat treatment (step S107), gate electrode formation (step S108), interlayer insulating film formation (step S109), source electrode formation (step S110), and drain electrode formation (step S111).

In the semiconductor device manufacturing method of the second embodiment, in addition to the semiconductor device manufacturing method of the first embodiment, carbon ion implantation (step S201), third heat treatment (step S202), and fourth heat treatment (step 5203) are performed.

In step S101, first, a first mask material is formed by patterning using photolithography and etching. Then, by using the first mask material as an ion implantation mask, aluminum (Al), which is a p-type impurity, is ion-implanted into the drift region 14. By the ion implantation, the p-well region 16 is formed.

Before forming the silicon oxide film in step S105, aluminum (Al) and carbon (C) are ion-implanted into the silicon carbide layer. The p-well region 16 contains aluminum (Al) and carbon (C).

In step S202, a third heat treatment is performed. The third heat treatment is performed at the first temperature before forming the silicon oxide film. The third heat treatment is performed after activation annealing.

The third heat treatment is performed in an atmosphere containing plasmatized hydrogen gas (H₂). The partial pressure of the hydrogen gas in the atmosphere of the third heat treatment is, for example, equal to or more than 0.1% and equal to or less than 4%. The partial pressure of the hydrogen gas in the atmosphere of the third heat treatment is preferably equal to or more than 0.2% and equal to or less than 1%, more preferably equal to or more than 0.3% and equal to or less than 0.5%. Typically, the partial pressure of the hydrogen gas in the atmosphere of the third heat treatment is about 0.3%. Dilution using argon gas, helium gas, nitrogen gas, and the like is performed.

For example, a plasmatized hydrogen gas (H₂) is supplied to a reaction furnace containing the silicon carbide layer 10 to perform heat treatment.

The first temperature of the third heat treatment is, for example, equal to or more than 0° C. and equal to or less than 150° C. The first temperature of the third heat treatment is preferably equal to or more than 10° C. and equal to or less than 100° C., more preferably equal to or more than 20° C. and equal to or less than 50° C. The first temperature of the third heat treatment is typically about 50° C. Since the concentration of plasmatized hydrogen is suppressed to be equal to or less than 4%, substrate surface etching is suppressed at a temperature equal to or less than 150° C., substrate surface etching hardly occurs at a temperature equal to or less than 100° C., and substrate surface etching does not occur at all at a temperature equal to or less than 50° C.

There is a correlation between the hydrogen concentration and the treatment temperature, and the higher the hydrogen concentration, the lower the temperature of the treatment. For example, when the hydrogen concentration is equal to or less than 4%, the treatment temperature is preferably equal to or less than 50° C. When the hydrogen concentration is equal to or less than 1%, the treatment temperature is preferably equal to or less than 100° C. When the hydrogen concentration is equal to or less than 0.5%, the treatment temperature is preferably equal to or less than 150° C.

In addition, the higher the treatment temperature, the more energy the plasma has, which is effective. The treatment temperature is equal to or more than 0° C., preferably equal to or more than 10° C., and more preferably equal to or more than 20° C. Typically, the concentration of plasmatized hydrogen is 0.3%, and the treatment temperature is 50° C.

By the third heat treatment, carbon is desorbed from the surface of the silicon carbide layer 10, and the surface of the silicon carbide layer 10 becomes a silicon-rich surface.

If the hydrogen concentration is lower than 0.1%, it is difficult to sufficiently desorb carbon. Therefore, the hydrogen concentration is preferably equal to or more than 0.2%, more preferably equal to or more than 0.3%. If the hydrogen concentration exceeds 1%, silicon is also desorbed and the substrate surface starts to be etched. If the hydrogen concentration exceeds 4%, the substrate surface is greatly etched. That is, the hydrogen concentration is equal to or more than 0.1% and equal to or less than 4%, preferably equal to or more than 0.2% and equal to or less than 1%, and more preferably equal to or more than 0.3% and equal to or less than 1%. Typically, the hydrogen concentration is about 0.3%. In the third heat treatment, the surface is not etched. Therefore, a silicon-rich surface is obtained.

The plasmatized hydrogen removes C on the surface, and is desorbed from the surface mainly as CH₄ gas. Since hydrogen preferentially reacts with C, Si remains. Since the plasmatized hydrogen reacts with C near the surface and is deactivated, C on the surface can be selectively removed without damaging the film surface. After the silicon-rich surface is formed in a thickness of about 1 nm to 5 nm, the plasmatized hydrogen is deactivated on the silicon-rich surface. Therefore, there is no effect on a portion deeper than the silicon-rich surface, and the reaction stops. The required heat treatment time is equal to or more than 0.5 minutes and equal to or less than 25 minutes, and there is no change even if the heat treatment continues for more than that. Therefore, the typical treatment time is, for example, 30 minutes.

By forming a silicon-rich layer on the surface, it is possible to prevent substrate oxidation due to the oxidizing agent (oxygen, water, ozone, and the like) during the subsequent formation of silicon oxide and the excess oxygen in the silicon oxide film during the first heat treatment. Then, since oxygen is supplied by performing the second heat treatment, the surplus silicon is finally converted into a good silicon oxide film having no oxygen deficiency. Since the surplus silicon is converted into silicon oxide by the second heat treatment, the amount of silicon in the silicon-rich layer of the surface may be increased with a margin.

In step S203, a fourth heat treatment is performed. The fourth heat treatment is performed at the second temperature before the first heat treatment after forming the silicon oxide film.

The fourth heat treatment is performed in an atmosphere containing hydrogen gas (H₂). The partial pressure of the hydrogen gas in the atmosphere of the fourth heat treatment is, for example, equal to or more than 0.1% and equal to or less than 10%. The partial pressure of the hydrogen gas in the atmosphere of the fourth heat treatment is preferably equal to or more than 0.2% and equal to or less than 5%, more preferably equal to or more than 0.3% and equal to or less than 5%.

For example, a hydrogen gas (H₂) is supplied to the reaction furnace containing the silicon carbide layer 10 to perform heat treatment.

The second temperature of the fourth heat treatment is, for example, equal to or more than 1200° C. and equal to or less than 1600° C. The second temperature is, for example, higher than the first temperature.

By the fourth heat treatment, a part of oxygen is desorbed from the silicon oxide film. The silicon oxide film becomes a film lacking oxygen.

Excess oxygen weakly bonded to silicon may remain in the silicon oxide film formed at a low temperature. There is a risk that the oxygen weakly bonded to silicon reaches the substrate during the first heat treatment to oxidize the substrate. However, it is possible to desorb the weakly bonded oxygen from the silicon oxide film by the fourth heat treatment. In this manner, the silicon oxide film becomes a film lacking oxygen. By using the silicon oxide film as a film lacking oxygen, it is possible to suppress the substrate from being oxidized during the first heat treatment.

If the hydrogen concentration is lower than 0.01%, it is difficult to sufficiently desorb oxygen in the oxide film. Therefore, the hydrogen concentration is preferably equal to or more than 0.03, more preferably equal to or more than 0.05%. If the hydrogen concentration exceeds 5%, the silicon oxide film itself starts to be etched although the amount of etching is very small, and if the hydrogen concentration exceeds 10%, the silicon oxide film is greatly etched. That is, the hydrogen concentration is equal to or more than 0.01% and equal to or less than 10%, preferably equal to or more than 0.03% and equal to or less than 5%, and more preferably equal to or more than 0.05% and equal to or less than 5%.

It is preferable that the higher the temperature, the lower the hydrogen concentration. The higher the temperature of hydrogen, the more damage the hydrogen causes to the equipment chamber and the like. Therefore, low-concentration hydrogen is required. At a temperature equal to or more than 1500° C., the H₂ concentration is preferably equal to or less than 0.1%. At a temperature equal to or more than 1350° C., the H₂ concentration is preferably equal to or less than 0.5%. At a temperature equal to or more than 1200° C., the H₂ concentration is preferably equal to or less than 1.0°.

In the low-temperature deposited oxide film generated by this process, there are a large amount of dangling bonds of silicon, electrons are supplied to hydrogen, and hydrogen is dissociated to increase reactivity. Therefore, treatment at low temperature and low concentration has a sufficient effect. Typically, the treatment temperature is 1250° C., and the hydrogen concentration is 0.3%. In the fourth heat treatment, the weakly bonded oxygen in the silicon oxide film is desorbed without causing the etching of the silicon oxide film, so that a silicon oxide film lacking oxygen is obtained.

The silicon oxide film lacking oxygen is, in other words, a silicon-rich oxide film. By forming the silicon oxide film lacking oxygen, it is possible to prevent substrate oxidation due to excess oxygen in the silicon oxide film during the subsequent first heat treatment. On the other hand, during the first heat treatment, surplus silicon is easily nitrided, and a larger amount of nitrogen is introduced into the silicon oxide film. However, by performing the second heat treatment, oxygen that has been deficient is supplied, nitrogen is substituted by oxygen, and nitrogen is emitted to the outside. Finally, a good silicon oxide film with no nitrogen defects and no oxygen deficiencies is obtained. Due to the surplus silicon, the amount of nitrogen in the oxide film due to the first heat treatment increases, but the nitrogen is removed by the second heat treatment. Therefore, it is desirable to make a sufficiently silicon-rich silicon oxide film by reliably removing the weakly bonded oxygen in the silicon oxide film by the fourth heat treatment.

The semiconductor device manufacturing method other than the carbon ion implantation (step S201), the third heat treatment (step S202), and the fourth heat treatment (step S203) is the same as the semiconductor device manufacturing method of the first embodiment.

By the semiconductor device manufacturing method described above, the MOSFET 100 shown in FIG. 1 is formed.

Next, the function and effect of the semiconductor device manufacturing method of the second embodiment will be described.

When aluminum (Al) is ion-implanted into the silicon carbide layer by p-type impurity ion implantation (step S101), carbon vacancies are formed in the silicon carbide layer by the kinetic energy of the ions.

The presence of carbon vacancies in the silicon carbide layer reduces the hall mobility of the carriers in the silicon carbide layer. As the hall mobility decreases, the on-resistance of the MOSFET increases.

The semiconductor device manufacturing method of the second embodiment includes the carbon ion implantation (step S201). By introducing carbon into the silicon carbide layer, carbon atoms can easily enter the carbon vacancies during activation annealing. Therefore, the amount of carbon vacancies in the silicon carbide layer is reduced. As a result, the increase in the on-resistance of the MOSFET is suppressed.

When the silicon oxide film is formed in step S105, the surface of the silicon carbide layer is oxidized. For example, even when the silicon oxide film is formed by low-temperature vapor phase growth, the surface of the silicon carbide layer is oxidized by oxygen present in the atmosphere. When the silicon carbide layer is oxidized, carbon vacancies are formed in the silicon carbide layer.

When carbon vacancies are formed in the silicon carbide layer, for example, in the first heat treatment performed in an atmosphere containing nitrogen gas, nitrogen enters the carbon vacancies to be become an n-type dopant. Therefore, the threshold voltage of the MOSFET is reduced.

The semiconductor device manufacturing method of the second embodiment includes the third heat treatment (step S202). The third heat treatment is performed in an atmosphere containing hydrogen gas (H₂) before forming the silicon oxide film.

By the third heat treatment, carbon is desorbed from the surface of the silicon carbide layer 10, and the surface of the silicon carbide layer 10 becomes a silicon-rich surface. Since the surface of the silicon carbide layer 10 is rich in silicon, the formation of carbon vacancies in the silicon carbide layer is suppressed when the silicon oxide film is formed. Therefore, the decrease in the threshold voltage of the MOSFET is suppressed.

When oxygen reaches the surface of the silicon carbide layer, the silicon is preferentially oxidized. For this reason, on the silicon-rich surface, a grace period is given before the silicon carbide layer is oxidized. If the insulating film formation ends within the grace period, the silicon carbide layer is not be oxidized. Therefore, the silicon oxide film can be formed without forming carbon vacancies in the silicon carbide layer.

The partial pressure of the hydrogen gas in the atmosphere of the third heat treatment is preferably equal to or more than 0.1%, more preferably equal to or more than 0.2%, and even more preferably equal to or more than 0.3%. By increasing the partial pressure of the hydrogen gas in the atmosphere, the desorption of carbon from the surface of the silicon carbide layer 10 is further promoted.

In the first heat treatment performed in an atmosphere containing nitrogen gas, it is considered that oxygen (particularly, excess oxygen weakly bonded to silicon) in the silicon oxide film formed in step S105 reaches the surface of the silicon carbide layer 10 and accordingly, the surface of the silicon carbide layer 10 is oxidized. When the surface of the silicon carbide layer 10 is oxidized, carbon vacancies are formed on the surface of the silicon carbide layer. When carbon vacancies are formed in the silicon carbide layer, nitrogen enters the carbon vacancies to become an n-type dopant. Therefore, the threshold voltage of the MOSFET is reduced.

The semiconductor device manufacturing method of the second embodiment includes the fourth heat treatment (step S204). The fourth heat treatment is performed in an atmosphere containing hydrogen gas (H₂) before the first heat treatment.

By the fourth heat treatment, a part of oxygen is desorbed from the silicon oxide film formed in step S105. The fourth heat treatment reduces the amount of oxygen in the silicon oxide film. The silicon oxide film becomes a film lacking oxygen. Oxygen vacancies are formed in the silicon oxide film.

By reducing the amount of oxygen in the silicon oxide film, oxidation of the surface of the silicon carbide layer 10 during the first heat treatment performed in an atmosphere containing nitrogen gas is suppressed.

Therefore, the formation of carbon vacancies on the surface of the silicon carbide layer is suppressed. As a result, the decrease in the threshold voltage of the MOSFET is suppressed.

The oxygen vacancies formed in the silicon oxide film by the fourth heat treatment are filled with nitrogen during the first heat treatment performed in an atmosphere containing nitrogen gas, thereby forming nitrogen defects. The nitrogen defects formed are reduced by the second heat treatment performed in an atmosphere containing nitrogen oxide gas (NOx).

In addition, by including the fourth heat treatment, the temperature of the first heat treatment can be raised or the time of the first heat treatment can be increased as compared with the semiconductor device manufacturing method of the first embodiment. This is because the oxidation of the surface of the silicon carbide layer 10 during the first heat treatment is suppressed. By raising the temperature of the first heat treatment or increasing the time of the first heat treatment, it is possible to further increase the nitrogen concentration in the interface termination region 40.

The partial pressure of the hydrogen gas in the atmosphere of the fourth heat treatment is preferably equal to or more than 0.1%, more preferably equal to or more than 0.2%, and even more preferably equal to or more than 0.3%. By increasing the partial pressure of the hydrogen gas in the atmosphere, the desorption of oxygen in the silicon oxide film is further promoted.

The second temperature of the fourth heat treatment is preferably equal to or more than 1200° C., more preferably equal to or more than 1300° C., and even more preferably equal to or more than 1400° C. By setting the second temperature in the above range, the desorption of oxygen in the silicon oxide film is further promoted.

The second temperature of the fourth heat treatment is preferably equal to or less than 1600° C., more preferably equal to or less than 1500° C. By setting the second temperature in the above range, the decrease in the thickness of the silicon oxide film is suppressed.

The second temperature of the fourth heat treatment is preferably higher than the first temperature of the third heat treatment. By increasing the second temperature, the thickness of the silicon oxide film is further reduced, but excess oxygen in the silicon oxide film can be reliably removed.

It is preferable to form a silicon-rich silicon oxide substrate surface, which has a sufficient amount of excess silicon, by the third heat treatment. It is preferable to form a silicon-rich silicon oxide film, which has a sufficient amount of excess silicon, by the fourth heat treatment. Since each heat treatment has an effect of preventing the oxidation of the silicon carbide substrate surface during the first heat treatment, the first heat treatment can be performed for a longer time, and accordingly, the amount of interface nitrogen increases. On the other hand, the amount of nitrogen in the silicon oxide film increases during the first heat treatment. However, by the second heat treatment, it is possible to remove nitrogen in the silicon oxide film without changing the amount of interface nitrogen. It is preferable to perform the third heat treatment and the fourth heat treatment even after the first heat treatment so that silicon remains at the interface or in the silicon oxide film. The surplus silicon is oxidized by the second heat treatment and converted into silicon oxide.

As described above, according to the second embodiment, a semiconductor device manufacturing method is realized in which the nitrogen concentration in the interface termination region is high and the amount of nitrogen defects and carbon defects in the insulating layer is reduced.

As described above, in the first and second embodiments, the case of 4H—SiC has been described as an example of the crystal structure of silicon carbide. However, embodiments can also be applied to silicon carbide having other crystal structures, such as 6H—SiC and 3C—SiC.

In addition, in the first and second embodiments, the case where the gate insulating layer 28 is provided on the silicon face or the m face of the silicon carbide layer has been described as an example. However, embodiments can also be applied to a case where the gate insulating layer 28 is provided on the other faces of the silicon carbide layer, for example, a carbon face, an a face, and a (0-33-8) face.

In addition, in the first and second embodiments, a method of manufacturing a MOSFET having a planar gate structure has been described as an example. However, embodiments can be applied to a method of manufacturing a MOSFET having a trench gate structure in which a gate electrode is formed in a trench of a silicon carbide layer.

In addition, in the first and second embodiments, the method of manufacturing an n-channel MOSFET has been described as an example. However, embodiments can also be applied to a method of manufacturing an n-channel insulated gate bipolar transistor (IGBT).

In addition, in the first and second embodiments, the method of manufacturing an n-channel MOSFET has been described as an example. However, embodiments can also be applied to a method of manufacturing a p-channel MOSFET or a p-channel IGBT without being limited to the n-channel MOSFET.

In addition, in the first and second embodiments, the method of manufacturing a MOSFET has been described as an example. However, embodiments can also be applied to a method of manufacturing a termination region provided around an element region, for example.

While certain embodiments have been described, these embodiments have been presented by way of example only, and are not intended to limit the scope of the inventions. Indeed, the semiconductor device manufacturing method described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device manufacturing method, comprising:
forming a silicon oxide film on a surface of a silicon carbide layer;
performing a first heat treatment in an atmosphere containing nitrogen gas at a temperature equal to or more than 1200° C. and equal to or less than 1600° C.; and
performing a second heat treatment in an atmosphere containing nitrogen oxide gas at a temperature equal to or more than 750° C. and equal to or less than 1050° C.

2. The method according to claim 1,
wherein a partial pressure of the nitrogen gas in the atmosphere during the first heat treatment is equal to or more than 99%.

3. The method according to claim 1,
wherein the silicon oxide film is formed by vapor phase growth.

4. The method according to claim 1,
wherein the silicon oxide film is formed at a temperature equal to or less than 600° C.

5. The method according to claim 1,
wherein a time period of the first heat treatment is equal to or more than one hour.

6. The method according to claim 1, further comprising:
performing a third heat treatment on the silicon carbide layer at a first temperature in an atmosphere containing plasmatized hydrogen gas before the forming the silicon oxide film.

7. The method according to claim 6,
wherein the first temperature is equal to or more than 0° C. and equal to or less than 150° C.

8. The method according to claim 1, further comprising:
performing a fourth heat treatment on the silicon carbide layer at a second temperature in an atmosphere containing hydrogen gas before the performing the first heat treatment after the forming the silicon oxide film.

9. The method according to claim 8,
wherein the second temperature is equal to or more than 1200° C. and equal to or less than 1600° C.

10. The method according to claim 1, further comprising:
performing a third heat treatment on the silicon carbide layer at a first temperature in an atmosphere containing plasmatized hydrogen gas before the forming the silicon oxide film; and
performing a fourth heat treatment on the silicon carbide layer at a second temperature higher than the first temperature in an atmosphere containing hydrogen gas before the performing the first heat treatment after the forming the silicon oxide film.

11. The method according to claim 1, further comprising:
ion-implanting aluminum (Al) and carbon (C) into the silicon carbide layer before the forming the silicon oxide film.

12. The method according to claim 1,
wherein a thickness of the silicon oxide film is equal to or more than 30 nm and equal to or less than 100 nm.

13. The method according to claim 1, further comprising:
forming a gate electrode on the silicon oxide film.
